(19) United States
(12) Patent Application Publication
(10) Pub. No.: US 2018/0095111 A1
(43) Pub. Date: Apr. 5, 2018

(54) COAXIAL PROBE CARD DEVICE

(71) Applicant: MPI Corporation, Chu-pei City (TW)

(72) Inventors: Chin-Yi Tsai, Chu-pei City (TW); Chen-Chih Yu, Chu-pei City (TW); Yi-Chia Huang, Chu-pei City (TW); Cheng-Nien Su, Chu-pei City (TW); Chung-Chi Lin, Chu-pei City (TW)

(21) Appl. No.: 15/709,620

(22) Filed: Sep. 20, 2017

(30) Foreign Application Priority Data
Oct. 4, 2016 (TW) 105132110
Aug. 15, 2017 (TW) 106127681

(51) Int. Cl. G01R 1/067; G01R 1/073

(52) U.S. Cl. CPC G01R 1/06733; G01R 1/07314

(57) ABSTRACT

A coaxial probe card device includes a substrate, a plurality of probe holders, and a plurality of probes. The substrate has a through hole. The plurality of probe holders is disposed on the substrate and is configured in a radial manner surrounding the through hole by using the through hole of the substrate as a center. Each probe holder has a probe slot, and the probe slot is inclined with respect to a surface of the substrate and extends towards the through hole of the substrate. The probes are individually disposed in the probe slots of the probe holders.

### CROSS-REFERENCES TO RELATED APPLICATIONS

This non-provisional application claims priority under 35 U.S.C. § 119(a) to Patent Application No. 105132110 filed in Taiwan, R.O.C. on Oct. 4, 2016 and Patent Application No. 106127681 filed in Taiwan, R.O.C. on Aug. 15, 2017, the entire contents of which are hereby incorporated by reference.

### BACKGROUND

### Technical Field

The present invention relates to a probe card device, and in particular, to a coaxial probe card device that is applied to integrated circuit testing.

### Related Art

In recent years, applications of an integrated circuit become popular gradually. After the integrated circuit is manufactured, to screen out defective products, usually a test signal is transmitted to the integrated circuit by using a test device to test whether functions of the integrated circuit match expectations, so as to control a factory yield rate of integrated circuits. Herein, by a conventional test technology, a probe device directly contacts a welding pad or an input/output (I/O) pad on the integrated circuit to be detected, the test device transmits the test signal to the integrated circuit by using the probe, and then the probe sends a test result back to the test device for analysis. In various probe structures used for testing the integrated circuit, a coaxial probe is most suitable for the integrated circuit that needs to be tested by using a high-frequency signal.

### SUMMARY

A coaxial probe card device provided in the present invention mainly includes a substrate, a first arc-shaped probe holder, a second arc-shaped probe holder, a first probe group, and a second probe group. The substrate has a through hole. The first arc-shaped probe holder has a first inner arc surface and a first outer arc surface that is opposite to the first inner arc surface. The first inner arc surface and the first outer arc surface extend from one end of the first arc-shaped probe holder to the other end thereof. The first arc-shaped probe holder is fixedly disposed on the substrate at one end and is located on one side of the through hole, and the first inner arc surface of the first arc-shaped probe holder faces towards the through hole. The second arc-shaped probe holder has a second inner arc surface and a second outer arc surface that is opposite to the second inner arc surface. The second inner arc surface and the second outer arc surface extend from one end of the second arc-shaped probe holder to the other end thereof. The second arc-shaped probe holder is fixedly disposed on the substrate at one end and is located on the other side of the through hole to be opposite to the first arc-shaped probe holder, and the second inner arc surface of the second arc-shaped probe holder faces towards the through hole. The first probe group includes a plurality of first probes that is disposed on the first arc-shaped probe holder. Each first probe passes through the first inner arc surface from the first outer arc surface, to extend to the through hole of the substrate. The second probe group includes a plurality of second probes that is disposed on the second arc-shaped probe holder. Each second probe passes through the second inner arc surface from the second outer arc surface, to extend to the through hole of the substrate.

The present invention further provides another coaxial probe card device that mainly includes a substrate, a plurality of probe holders, and a plurality of probes. The substrate has a through hole. The plurality of probe holders is disposed on the substrate and is configured in a radial manner surrounding the through hole by using the through hole of the substrate as a center. Each probe holder has a probe slot, and the probe slot is inclined with respect to a surface of the substrate and extends towards the through hole of the substrate. The probes are individually disposed in the probe slots of the probe holders.

In an embodiment, the probes each includes a probe body and a detection member, where the probe body has a first section and a second section, the first section of the probe body is fixed at the probe holder, the detection member is fixed at the second section of the probe body, there is a bending angle between the first section and the second section of the probe body, and bending angles of at least two of the plurality of probes are different. The coaxial probe card device further includes a limit assembly that is sheathed around and fixed at probe bodies of the plurality of probes, where the limit assembly includes a portion to pass through, second sections of the probe bodies of the plurality of probes pass through the portion to pass through, the detection member penetrates out of the portion to pass through, and an adhesive is disposed between the portion to pass through and the probe bodies, to fixedly bond the probe bodies and the limit assembly.

### BRIEF DESCRIPTION OF THE DRAWINGS

FIG. 1 is a three-dimensional schematic diagram according to a first embodiment of the present invention;

FIG. 2 is a schematic top view according to a first embodiment of the present invention;

FIG. 3 is a schematic front view according to a first embodiment of the present invention;

FIG. 4 is a schematic side view according to a first embodiment of the present invention;

FIG. 5 is a three-dimensional schematic diagram according to a second embodiment of the present invention;

FIG. 6 is a schematic top view according to a second embodiment of the present invention;

FIG. 7 is a schematic front view according to a second embodiment of the present invention;

FIG. 8 is a schematic side view according to a second embodiment of the present invention;

FIG. 9 is a three-dimensional schematic diagram 1 of a first example of a coaxial probe structure of a coaxial probe card device;

FIG. 10 is a three-dimensional schematic diagram 2 of a first example of a coaxial probe structure of a coaxial probe card device;

FIG. 11 is an enlarged view of an end face of a probe body of a first example of a coaxial probe structure of a coaxial probe card device;

FIG. 12 is a three-dimensional schematic diagram 1 of a second example of a coaxial probe structure of a coaxial probe card device;

FIG. 13 is a three-dimensional schematic diagram 2 of a second example of a coaxial probe structure of a coaxial probe card device;

FIG. 14 is an enlarged view of an end face of a probe body of a second example of a coaxial probe structure of a coaxial probe card device;

FIG. 15 is a three-dimensional schematic diagram of a third embodiment of a coaxial probe card device;

FIG. 16 is a top view of a third embodiment of a coaxial probe card device;

FIG. 17 is a sectional view of a third embodiment of a coaxial probe card device;

FIG. 18 is a partially enlarged view of a position circled by 18 in FIG. 17;

FIG. 19 is a three-dimensional diagram of a local structure of a probe of a third embodiment of a coaxial probe card device;

FIG. 20 is a three-dimensional diagram of a local structure of a probe from different angles of view of a third embodiment of a coaxial probe card device;

FIG. 21 is a three-dimensional exploded view of a local structure of a third embodiment of a coaxial probe card device;

FIG. 22 is a three-dimensional diagram of a local structure of a third embodiment of a coaxial probe card device;

FIG. 23 is a three-dimensional perspective view of a local structure of a third embodiment of a coaxial probe card device; and

FIG. 24 is a top view of a local structure of a third embodiment of a coaxial probe card device.

### DETAILED DESCRIPTION

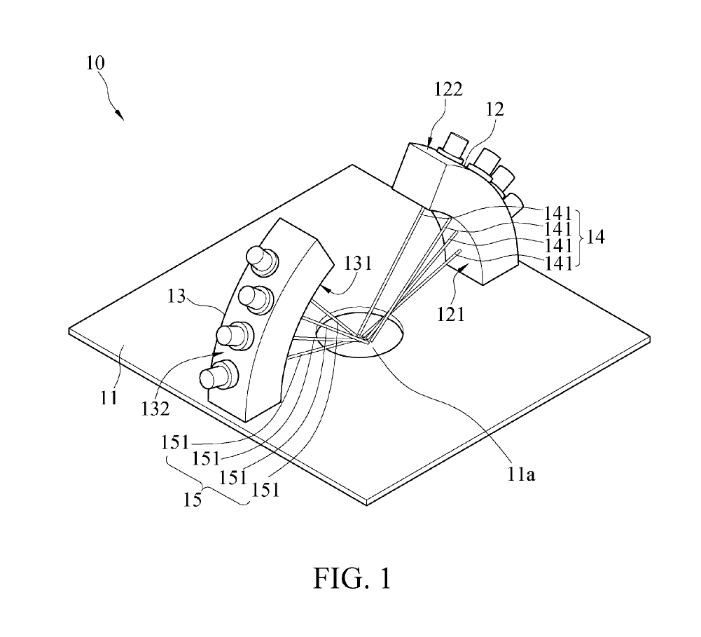

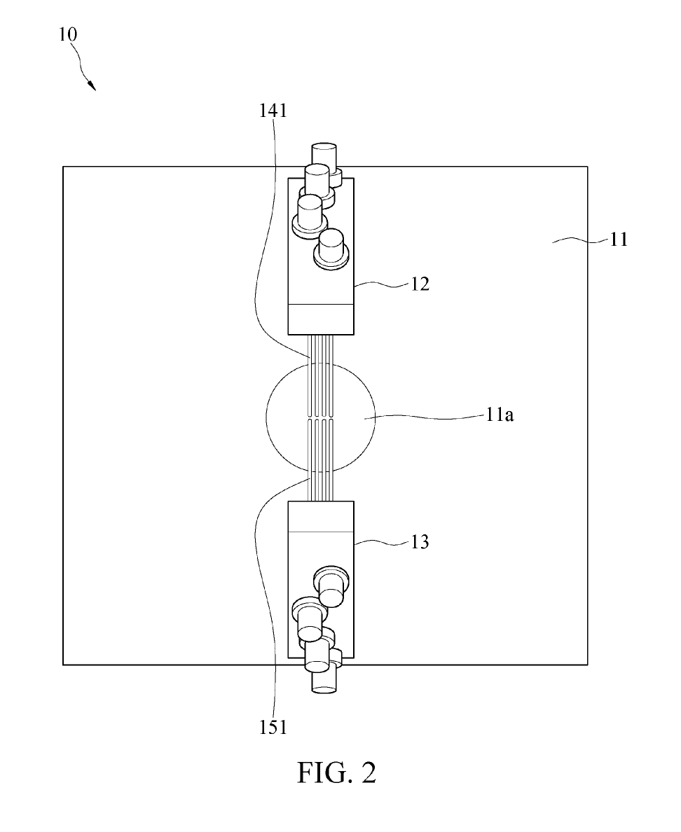

Referring to FIG. 1 to FIG. 4, FIG. 1 to FIG. 4 respectively are a three-dimensional schematic diagram, a schematic top view, a schematic front view, and a schematic side view according to a first embodiment of the present invention. A coaxial probe card device 10 is drawn. The coaxial probe card device 10 mainly includes a substrate 11, a first arc-shaped probe holder 12, a second arc-shaped probe holder 13, a first probe group 14, and a second probe group 15.

The substrate 11 has a through hole 11a that is located at the center of the substrate 11. The first arc-shaped probe holder 12 has a first inner arc surface 121 and a first outer arc surface 122 that is opposite to the first inner arc surface 121. The first inner arc surface 121 and the first outer arc surface 122 extend from one end of the first arc-shaped probe holder 12 to the other end thereof. The first arc-shaped probe holder 12 is erected on the substrate 11, is fixedly disposed on the substrate 11 at one end, and is located on one side of the through hole 11a. The first inner arc surface 121 of the first arc-shaped probe holder 12 faces towards the through hole 11a. The second arc-shaped probe holder 13 has a second inner arc surface 131 and a second outer arc surface 132 that is opposite to the second inner arc surface 131. The second inner arc surface 131 and the second outer arc surface 132 extend from one end of the second arc-shaped probe holder 13 to the other end thereof. The second arc-shaped probe holder 13 is fixedly disposed on the substrate 11 at one end and is located on the other side of the through hole 11a to be opposite to the first arc-shaped probe holder 12. The second inner arc surface 131 of the second arc-shaped probe holder 13 faces towards the through hole 11a.

The first probe group 14 includes a plurality of first probes 141 that is disposed on the first arc-shaped probe holder 12. Each first probe 141 passes through the first inner arc surface 121 from the first outer arc surface 122, to respectively extend to the through hole 11a of the substrate 11 in different orientations. Included angles between the first probes 141 and the substrate 11 are different from each other, and any two first probes 141 may be not coplanar with each other. The second probe group 15 includes a plurality of second probe 151 that are disposed on the second arc-shaped probe holder 13. Each second probe 151 passes through the second inner arc surface 131 from the second outer arc surface 132, to respectively extend to the through hole 11a of the substrate 11 in different orientations. Included angles between the second probes 151 and the substrate 11 are different from each other, and any two second probes 151 may be not coplanar with each other.

In this embodiment, the first probe holder 12 and the second probe holder 13 are erected on the substrate 11, and are fixedly disposed on the substrate 11 at one ends. Therefore, the first probes 141 and the second probes 151 may extend to the through hole 11a of the substrate 11 in different spatial orientations, and meanwhile the distances between the first probes 141 and the second probes 151 may be kept equal to each other and even the length of first probes 141 may also be equal to that of the second probes 151. In this way, an impedance difference between the first probes 141 and the second probes 151 may be minimized.

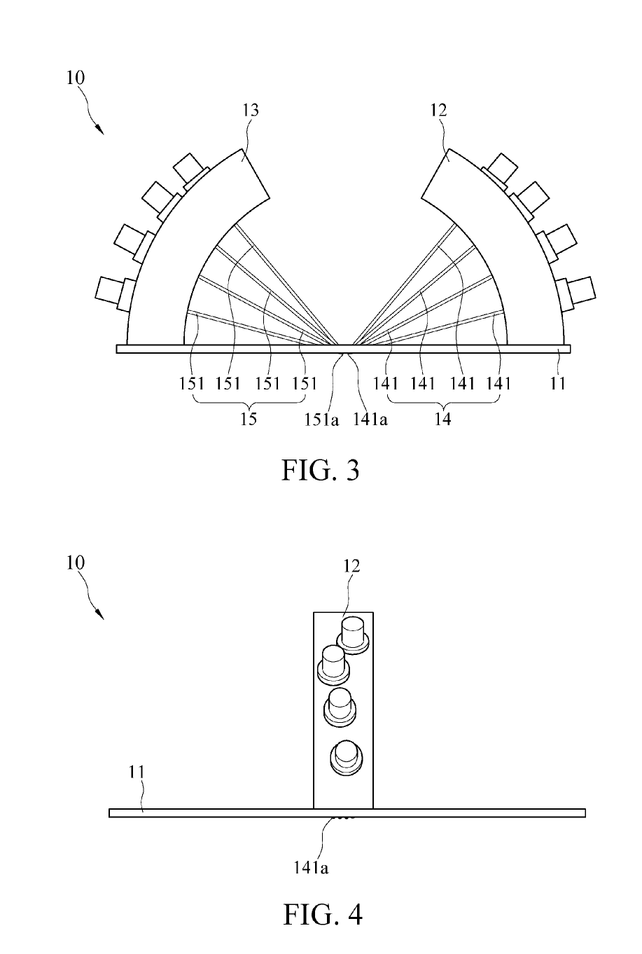

As shown in FIG. 3 and FIG. 4, each first probe 141 has a tip 141a, and each second probe 151 has a tip 151a. The tip 141a of each first probe 141 and the tip 151a of each second probe 151 pass through the through hole 11a of the substrate 11, so as to perform a probe test on a to-be-tested object below the through hole 11a. In this embodiment, the tips 141a of all the first probes 141 may be arranged in a straight line and be located on a same horizontal plane, and the tips 151a of all the second probe 151 may also be arranged in a straight line and be located on a same horizontal plane. Moreover, the straight line formed by the tips 141a of all the first probes 141 may be parallel to the straight line formed by the tips 151a of all the second probes 151.

In one aspect of this embodiment, each first probe 141 is coplanar with the second probe 151 that is located at an opposite side of the first probe 141, and is not coplanar with the remaining second probes 151. That is, each first probe 141 is merely coplanar with at most one of the second probes 151. However, it should be particularly noted that any two first probes 141 still are not coplanar with each other, and any two second probes 151 are not coplanar with each other either.

It should be particularly noted that the included angles between the first probes 141 and the substrate 11 are different from each other, and the included angles between the second probe 151 and the substrate 11 are also different from each other. Therefore, when an operator operates to lower the substrate to enable the tips 141a of the first probes 141 and the tips 151a of the second probes 151 to touch a welding pad of a to-be-tested object, pressures applied to the welding pad by the tips 141a of the first probes 141 are different, and pressures applied to the welding pad by the tips 151a of the second probes 151 are also different, resulting in a situation in which a surface of the welding pad is penetrated by the probes at inconsistent degrees. This type of minor stress difference may be ignored under most test conditions. However, to further correct to make stresses applied to the welding pad by the probes consistent, the length of each first probe 141 or second probe 151 may be adjusted, or the diameter of each first probe 141 or second probe 151 may be adjusted, so as to enable the stresses applied to the welding pad by the probes to be consistent. According to a calculation in mechanics of materials, when the material of the probe is kept unchanged, the stresses applied to the welding pad are inversely proportional to 3^{th} power of the length of the probe, and are proportional to 4^{th} power of the diameter of the probe. The first probes 141 or the second probes 151 may be of a coaxial structure. To cushion a stress when the probe test is performed, a larger diameter of a coaxial probe indicates a need of a longer length of the first probe 141 or the second probe 151.

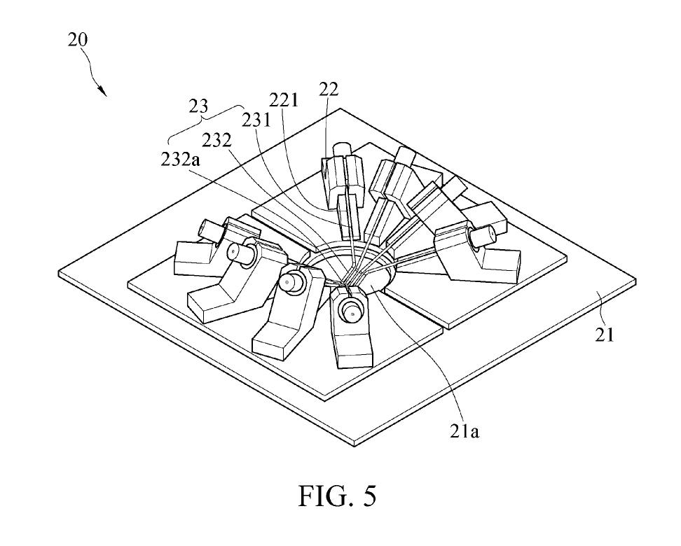

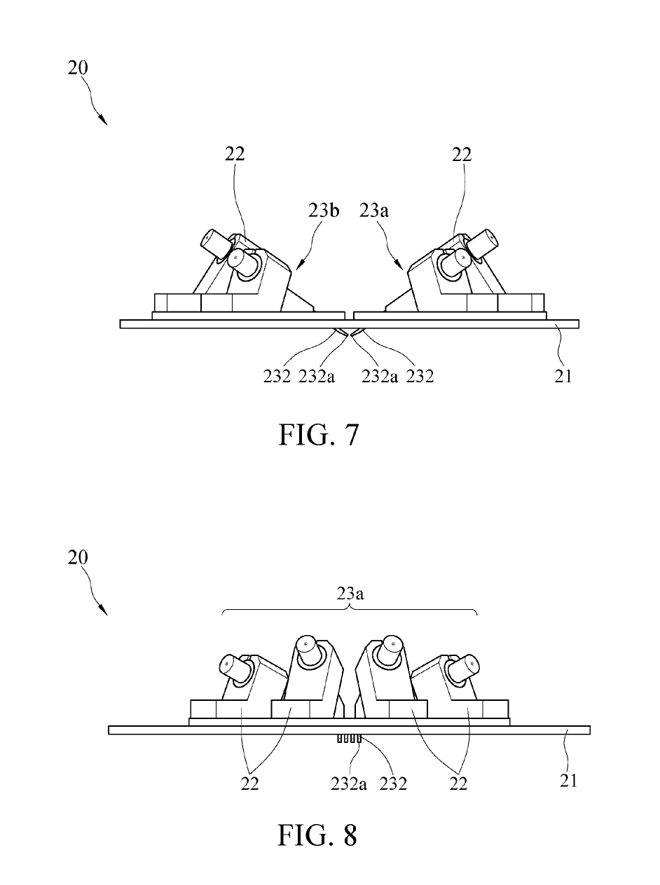

Referring to FIG. 5 to FIG. 8, FIG. 5 to FIG. 8 respectively are a three-dimensional schematic diagram, a schematic top view, a schematic front view, and a schematic side view according to a second embodiment of the present invention. A coaxial probe card device 20 is drawn. The coaxial probe card device 20 mainly includes a substrate 21, a plurality of probe holders 22, and a plurality of probes 23.

The substrate 21 has a through hole 21a. The plurality of probe holders 22 is disposed on the substrate 21 and is configured in a radial manner surrounding the through hole 21a by using the through hole 21a of the substrate 21 as a center. Each probe holder 22 has a probe slot 221, and the probe slot 221 is inclined with respect to a surface of the substrate 21 and extends towards the through hole 21a of the substrate 21. The probes 23 are individually disposed in the probe slots 221 of the probe holders 22.

In this embodiment, because the plurality of probe holder 22 is individually disposed on the substrate 21 and is configured in a radial manner surrounding the through hole 21a by using the through hole 21a of the substrate 21 as a center, the lengths of the probes 23 may be substantially equal to each other. In addition, each probe 23 is disposed on an exclusive probe holder 22 thereof. Therefore, if the probe is damaged and needs to be exchanged, only the damaged probe is exchanged.

In this embodiment, each probe 23 has a first section 231 and a second section 232. The first section 231 of each probe 23 is disposed in the probe slot 221 of each probe holder 22, and the second section 232 is bent with respect to the first section 231 and passes through the through hole 21a of the substrate 21. The lengths of the first sections 231 or the second sections 232 may substantially be the equal to each other.

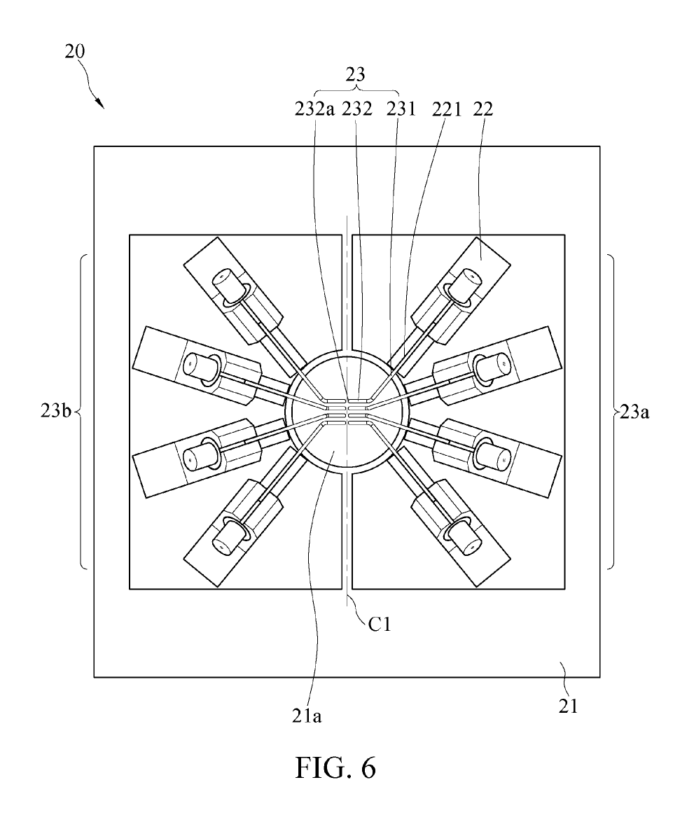

In this embodiment, the plurality of probes 23 may further be grouped into a first group 23a and a second group 23b. The probes 23 of the first groups 23a and the probes 23 of the second group 23b are disposed in a mirrored manner with respect to an axis of symmetry C1 passing through the center of the through hole 21a of the substrate 21. As shown in FIG. 6 to FIG. 8 again, the tips 232a of the second sections 232 of the probes 23 of the first groups 23a are arranged in a straight line and are located on a same horizontal plane, and the tips 232a of the second sections 232 of the probes 23 of the second group 23b are also arranged in a straight line and are located on a same horizontal plane. In addition, the straight line formed by the tips 232a of the second sections 232 of the probes 23 of the first groups 23a may be parallel to the straight line formed by the tips 232a of the second sections 232 of the probes 23 of the second group 23b.

In this embodiment, the probes 23 are configured in a radial manner with respect to the through hole 21a of the substrate 21, and are individually inclined with respect to a surface of the substrate 21, where the second sections 231 of any three probes 23 are not coplanar with each other.

A probe structure of the coaxial probe card device in the foregoing embodiments may be specially designed, and the following two examples are made.

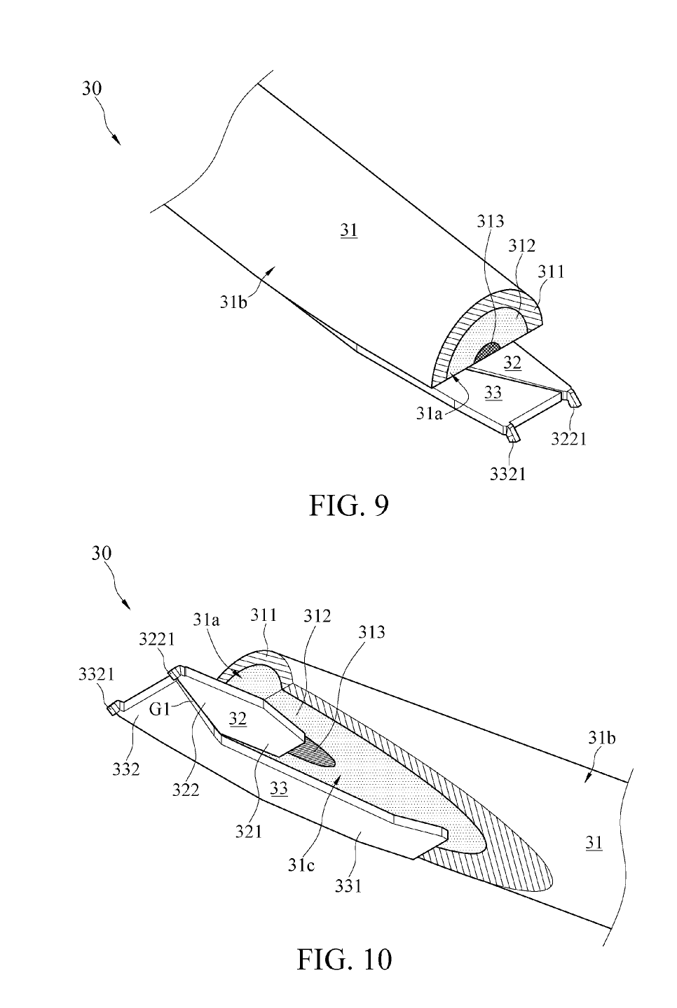

Referring to FIG. 9 and FIG. 10, FIG. 9 and FIG. 10 respectively are a three-dimensional schematic diagram 1 and a three-dimensional schematic diagram 2 of a first example of a coaxial probe structure of a coaxial probe card device. A coaxial probe structure 30 of a coaxial probe card device that is applicable to the present invention is drawn. The coaxial probe structure 30 mainly includes a probe body 31, a first metal sheet 32, and a second metal sheet 33.

The probe body 31 is in round bar-shaped, and successively includes, from outside to inside, an external conductor 311, an insulation layer 312, and an internal conductor 313 that are coaxially disposed. The external conductor 311 and the internal conductor 313 are insulated and isolated from each other by using the insulation layer 312. The probe body 31 has an end face 31a, a circumferential surface 31b, and a beveled surface 31c. The end face 31a is located at one end of the probe body 31, and a normal direction of the end face 31a is roughly parallel to an axial direction (the length direction) of the probe body 31. Moreover, the external conductor 311, the insulation layer 312, and the internal conductor 313 are all exposed out of the end face 31a. The circumferential surface 31b is defined by an outer surface of the external conductor 311. The beveled surface 31c extends towards the circumferential surface 31b from the end face 31a, and chamfers the external conductor 311, the insulation layer 312, and the internal conductor 313, so that the external conductor 311, the insulation layer 312, and the internal conductor 313 are partially exposed out of the beveled surface 31c. In other words, the beveled surface 31c substantially includes a tangent plane of the external conductor 311, a tangent plane of the insulation layer 312, and a tangent plane of the internal conductor 313.

The first metal sheet 32 includes a first fixed end 321 and a first protrusion end 322. The first fixed end 321 may be fixedly disposed at the beveled surface 31c of the probe body 31 by means of welding and may be electrically connected to a portion that is of the internal conductor 313 and that is exposed out of the beveled surface 31c. The first protrusion end 322 protrudes from the end face 31a of the probe body 31 and has a first projection 3221. The second metal sheet 33 includes a second fixed end 131 and a second protrusion end 332. The second fixed end 131 may be fixedly disposed at the beveled surface 31c of the probe body 31 by means of welding and may be electrically connected to a portion that is of the external conductor 311 and that is exposed out of the beveled surface 31c. The second protrusion end 332 protrudes from the end face 31a of the probe body 31 and has a second projection 3321. The first projection 1221 and the second projection 1321 are configured to perform a probe test on a to-be-tested object (DUT). It should be particularly noted that the first metal sheet 32 and the second metal sheet 33 are respectively defined to be configured to transmit a test signal and be grounded, or are respectively defined to be configured to be grounded and transmit a test signal. For example, the first metal sheet 32 is configured to transmit a test signal and the second metal sheet 33 is configured to be grounded. Therefore, the first metal sheet 32 is not connected to the second metal sheet 33.

Materials of the external conductor 311 and the internal conductor 313 of the probe body 31 in this example are metals, for example, brass, beryllium copper, tungsten steel, or rhenium tungsten. A material of the insulation layer 312 may be a polymeric composite material, for example, glass fiber, which has good mechanical strength, insulativity, and weatherability; or may be polytetrafluoroethylene (PTFE) or polyetheretherketone (PEEK).

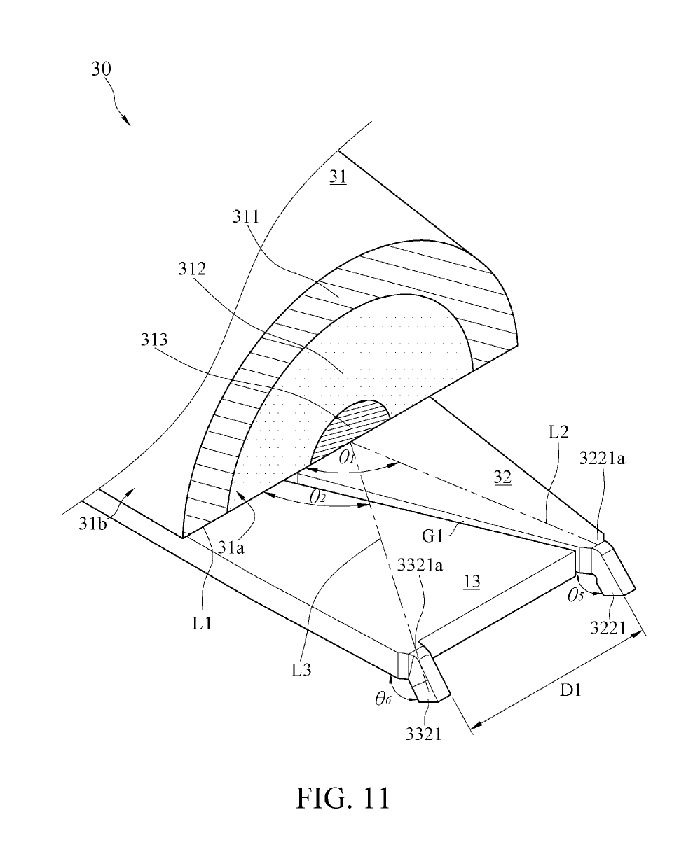

Referring to FIG. 11, FIG. 11 is an enlarged view of an end face 31a of the probe body 31 of the first example of the coaxial probe structure. An intersecting line L1 is defined at a position at which the end face 31a and the beveled surface 31c of the probe body 31 of the coaxial probe structure 30 in the first example are connected. A connection line L2 from a root portion 3221a of the first projection 3221 to the center of the end face 31a of the probe body 31 is vertical to the intersecting line L1. That is, an included angle θ₁ between L1 and L2 is 90 degrees. A connection line L3 from a root portion 1321a of the second projection 3321 to the center of the end face 31a of the probe body 31 is not vertical to the intersecting line L1. That is, an included angle θ₂ between L1 and L3 is not 90 degrees. The center of the end face 31a is equivalent to a center of a shape (a shape center) of the end face 31a. For example, when the end face 31a is rounded or elliptic, the center of the end face 31a is a circle center; and when the end face 31a is a regular polygon, the center of the end face 31a is an intersection point of all diagonals. It should be particularly noted that the distance D1 (from edge to edge) between the first projection 3221 and the second projection 3321 in the first example of the coaxial probe structure is smaller than the vertical distance between the center of the end face 31a and the circumferential surface 31b of the probe body 31.

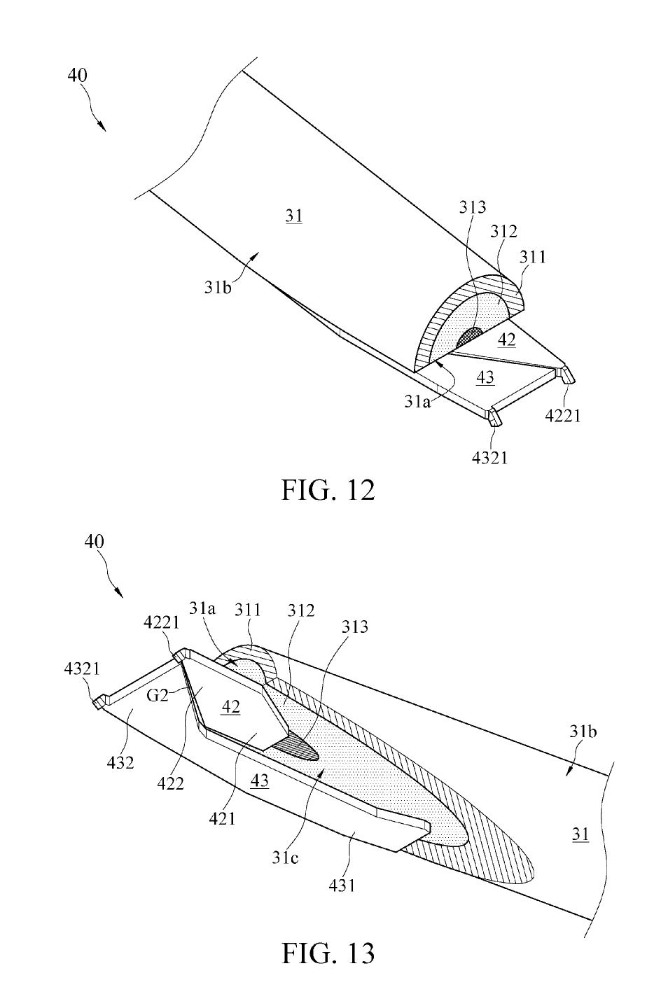

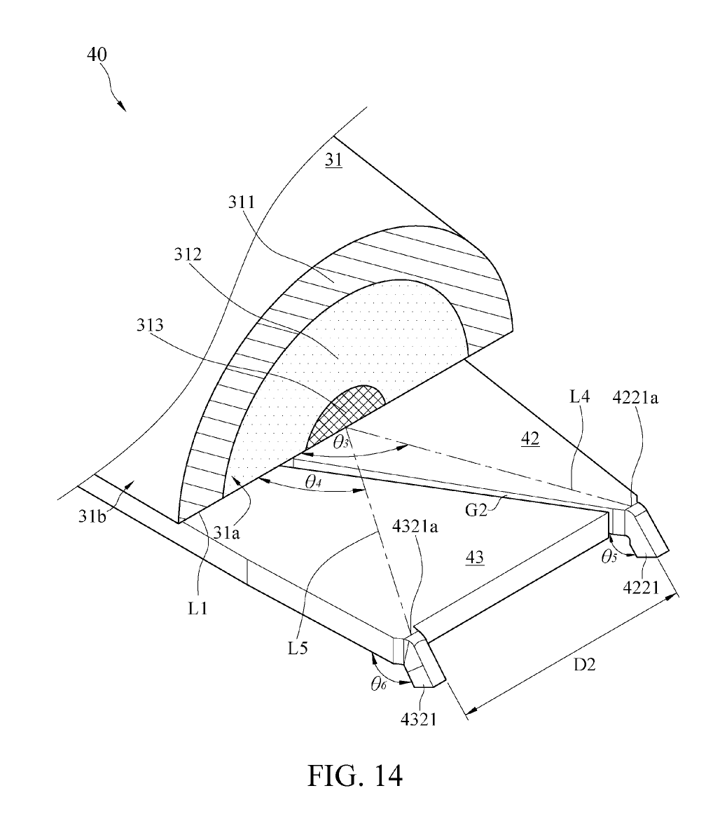

Referring to FIG. 12 to FIG. 14, FIG. 12 is a three-dimensional schematic diagram 1 of a second example of a coaxial probe structure of a coaxial probe card device; FIG. 13 is a three-dimensional schematic diagram 2 of a second example of a coaxial probe structure of a coaxial probe card device; and FIG. 14 is an enlarged view of an end face of a probe body of a second example of a coaxial probe structure of a coaxial probe card device. A coaxial probe structure 40 is drawn. The coaxial probe structure 40 mainly includes a probe body 31 a first metal sheet 42, and a second metal sheet 43. The first metal sheet 42 includes a first fixed end 421 and a first protrusion end 422. The first fixed end 421 may be fixedly disposed at the beveled surface 31c of the probe body 31 by means of welding and may be electrically connected to a portion that is of the internal conductor 313 and that is exposed out of the beveled surface 31c. The first protrusion end 422 protrudes from the end face 31a of the probe body 31 and has a first projection 4221. The second metal sheet 43 includes a second fixed end 431 and a second protrusion end 432. The second fixed end 431 may be fixedly disposed at the beveled surface 31c of the probe body 31 by means of welding and may be electrically connected to a portion that is of the external conductor 311 and that is exposed out of the beveled surface 31c. The second protrusion end 432 protrudes from the end face 31a of the probe body 31 and has a second projection 4321. In the first example of the coaxial probe structure that is stated above, the first metal sheet 42 and the second metal sheet 43 may be respectively defined to be configured to transmit a test signal and be grounded (or to be grounded and transmit a test signal). Therefore, the first metal sheet 42 is not connected to the second metal sheet 43.

The coaxial probe structure 40 in the second example mainly differs from the coaxial probe structure 30 in the first example in that a connection line L4 from a root portion 4221a of the first projection 4221 of the first metal sheet 42 to the center of the end face 31a of the probe body 31 is not vertical to the intersecting line L1. That is, an included angle θ₃ between L4 and L1 is not 90 degrees, or is greater than 90 degrees. A connection line L5 from a root portion 4321a of the second projection 4321 to the center of the end face 31a of the probe body 31 is not vertical to the intersecting line L1. That is, an included angle θ₄ between L1 and L5 is not 90 degrees, or is smaller than 90 degrees.

It should be particularly noted that the distance D2 (from edge to edge) between the first projection 4221 and the second projection 4321 in the second example of the coaxial probe structure is greater than the vertical distance between the center of the end face 31a of the probe body 31 and the circumferential surface 31b. When an integrated circuit is tested, if a conductor part that is of a coaxial probe structure and that is configured to transmit a test signal is excessively close to a conductor part that is of another adjacent coaxial probe structure and that is configured to be grounded, the test may be interfered. Therefore, in some processes of performing a probe test, adjacent coaxial probe structures may be spaced by a distance of more than one to-be-tested element (DUT), so that the adjacent coaxial probe structures do not interfere with each other. Regarding the second example of the coaxial probe structure, if the first metal sheet 42 in the second example is defined to be configured to transmit a test signal and the second metal sheet 43 is configured to be grounded, by enabling the connection line L4 from the root portion 4221a of the first projection 4221 of the first metal sheet 42 to the center of the end face 31a of the probe body 31 to be not vertical to the intersecting line L1, that is, enabling the first projection 4221 to deviate from the axial direction of the probe body 311 (or the internal conductor 313), a position that is originally relatively far away from the axial direction of the probe body 311 (or the internal conductor 313) or that is located at the projection 4321 in a length extension direction of the external conductor 313 may be enabled to approach towards the axial direction of the probe body 311 (or the internal conductor 313), and the volume of the second metal sheet 43 may further be decreased, so as to avoid interference to the test signal of the adjacent coaxial probe structure because the volume of the second metal sheet 43 is excessively large. That is, the second example of the coaxial probe structure may enable the coaxial probe structures to be arranged more closely. Therefore, there is no need to space by more than one to-be-tested element (DUT) to perform the probe test, but continuous tests may be performed, thereby improving performance of the probe test. In addition, the foregoing off-axis design may enable the distance between of the first projection 4221 and the second projection 4321 to be greater than, less than, or equal to the diameter of the coaxial probe structure; and this is selected according to a size of the used coaxial probe structure and requirements on a test (pad) distance.

Referring to FIG. 9 and FIG. 11 again, in the first example, both the first fixed end 321 of the first metal sheet 32 and the second fixed end 131 of the second metal sheet 33 do not protrude from the beveled surface 31c of the probe body 31, so as to prevent the adjacent coaxial probe structures from interfering with each other. Referring to FIG. 12 and FIG. 13 again, in the second example of the coaxial probe structure, the first fixed end 421 of the first metal sheet 42 and the second fixed end 431 of the second metal sheet 43 also do not protrude out from the beveled surface 31c of the probe body 31, so as to prevent the adjacent coaxial probe structures from interfering with each other. However, the first fixed end 421 and the second fixed end 431 may protrude out in other different conditions or considerations.

Referring to FIG. 10 again, in the first example, the first protrusion end 322 of the first metal sheet 32 and the second protrusion end 332 of the second metal sheet 33 are spaced by a gap G1 in a direction parallel to the beveled surface 31c. The gap G1 may be equal or not equal in width. In addition, when the gap G1 is not equal in width, the gap G1 may be gradually narrowed with the end face 31a that is away from the probe body 31. It should be particularly noted that the size of the gap G1 depends on the thicknesses of the first metal sheet 32 and the second metal sheet 33. In an implementation aspect, regardless of whether the gap G1 is equal or not equal in width, a minimum value of the width of the gap G1 is between one fifth and one tenth of the thicknesses of the first metal sheet 32 and the second metal sheet 33. It is learned from experimentation that if the minimum value of the width of the gap G1 is greater than one fifth of the thicknesses of the first metal sheet 32 and the second metal sheet 33, high frequency characteristics are weakened. However, if the minimum value of the width of the gap G1 is smaller than one tenth of the thicknesses of the first metal sheet 32 and the second metal sheet 33, a process difficulty is increased and a yield rate or reliability is decreased. That is, the gap G1 is selected by considering the thicknesses of the first metal sheet 32 and the second metal sheet 33, requirements on a test frequency, and a process yield rate (or reliability). Similarly, referring to FIG. 13 again, in the second example of the coaxial probe structure, the first protrusion end 422 of the first metal sheet 42 and the second protrusion end 432 of the second metal sheet 43 are spaced by a gap G2 in a direction parallel to the beveled surface 31c. Features of the gap G2 are the same as those of the gap G1 described above, and details are not described herein again.

Referring to FIG. 11 again, in the first example, the first projection 3221 is bent with respect to a surface of the first metal sheet 32, and defines a first included angle θ₅ with the surface of the first metal sheet 32. The second projection 3321 is bent with respect to a surface of the second metal sheet 33, and defines a second included angle θ₆ with the surface of the second metal sheet 33. θ₅ is substantially equal to θ₆, and both θ₅ and θ₆ may be in a range from 120 degrees to 135 degrees. Referring to FIG. 14 again, in the second example of the coaxial probe structure, the first projection 4221 is bent with respect to a surface of the first metal sheet 42, and defines a first included angle θ₅ with the surface of the first metal sheet 42. The second projection 4321 is bent with respect to a surface of the second metal sheet 43, and defines a second included angle θ₆ with the surface of the second metal sheet 43. Similarly, θ₅ is substantially equal to θ₆, and both θ₅ and θ₆ may be in a range from 120 degrees to 135 degrees. The first projection is bent with respect to the first metal sheet and the second projection is bent with respect to the second metal sheet because when the probe test is performed, an operator needs to observe whether the first projection and the second projection are aligned with a welding pad of the to-be-tested object. If the first projection and the second projection are not bent, visual field of a camera may be blocked by the probe body when a probe thrusts. As a result, it is difficult for the operator to observe whether the first projection and the second projection are aligned with the welding pad of the to-be-tested object. However, if there is another manner (for example, installing a camera having different viewing angles) for determining or observing whether the first projection and the second projection are aligned with the welding pad of the to-be-tested object, the first projection and the second projection may not be bent with respect to the first metal sheet and the second metal sheet. In addition, the first projection 4221 or the second projection 4321 is configured to contact an end face of the to-be-tested object, and may also have an included angle less than 10 degrees with the to-be-tested object or the first metal sheet 42 (or the second metal sheet 43), so as not to be completely parallel thereto.

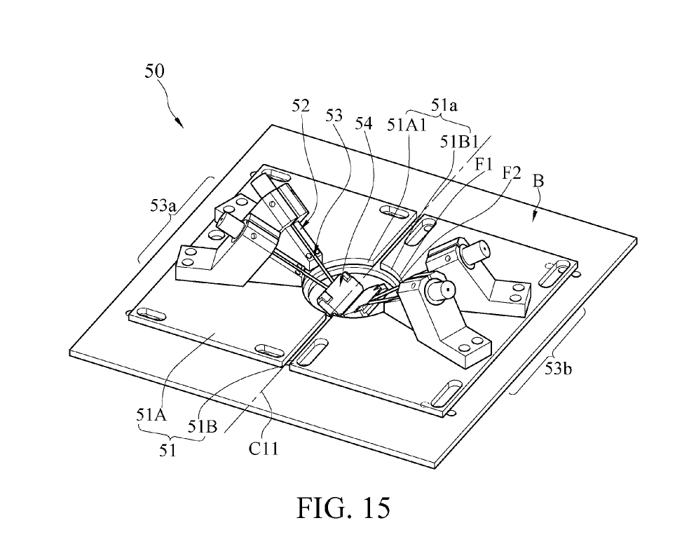

Referring to FIG. 15 to FIG. 17, FIG. 15 to FIG. 17 respectively are a three-dimensional schematic diagram, a top view, and a sectional view of a third embodiment according to the present invention. A coaxial probe card device 50 is drawn. The coaxial probe card device 50 mainly includes a substrate 51, a plurality of probe holders 52, a plurality of probes 53, and a limit assembly 54.

Referring to FIG. 15, the substrate 51 has a through hole 51a. The probe holders 52 are disposed on the substrate 51 and are arranged in a radial manner surrounding the through hole 51a by using the through hole 51a as a center. The probes 53 are disposed on the probe holder 52. The limit assembly 54 is sheathed around and fixed at portions of the probes 53 that extend into the through hole 51a. In this way, the limit assembly 54 supports the probe 53 to be stable when a probe test is performed, so as to prevent the probe 53 from generating an unexpected slide, thereby maintaining stability in work of the probe test. The substrate 51 has an upper surface F1 and a lower surface F2 that is opposite to the upper surface F1. When probe test is performed on a to-be-tested object (DUT), the lower surface F2 of the substrate 51 faces the to-be-tested object. The through hole 51a passes through the upper surface F1 and the lower surface F2 of the substrate 51. The probe holder 52 is disposed on the upper surface F1 of the substrate 51. The probe 53 is disposed on the probe holder 52 and extends into the through hole 51a to pass through the lower surface F2 of the substrate 51.

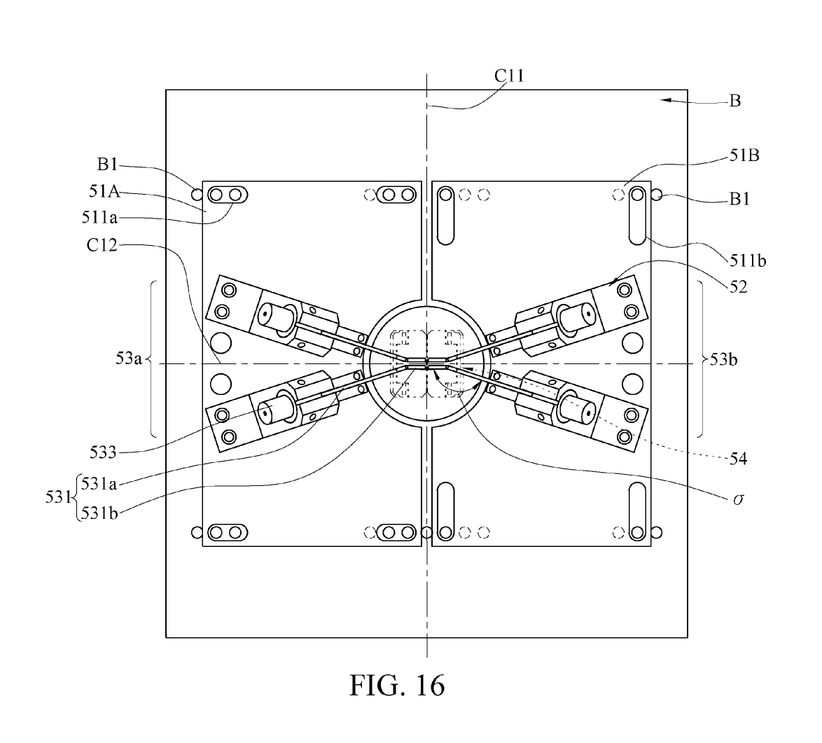

Referring to FIG. 15 and FIG. 16 again, in an embodiment, the substrate 51 includes a first substrate 51A and a second substrate 51B. The first substrate 51A has a first half hole 51A1, and the second substrate 51B has a second half hole 51B1. The first half hole 51A1 and the second half hole 51B1 both are semi-circular holes. The first substrate 51A and the second substrate 51B are symmetrically disposed to enable the first half hole 51A1 and the second half hole 51B1 to form a circular through hole 51a.

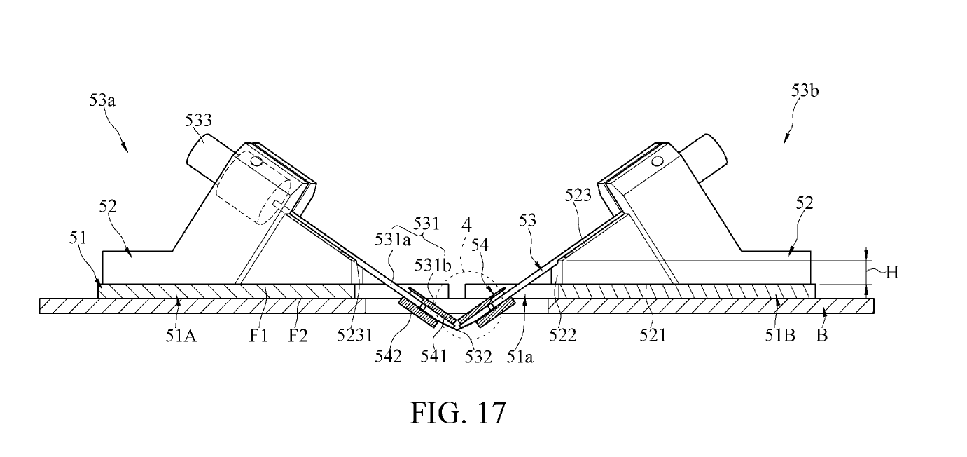

Referring to FIG. 15 and FIG. 17, in an embodiment, the probe 53 is fixed at the probe holder 52 in a manner of being inclined with respect to a surface of the substrate 51, and extends into the through hole 51a. Herein, the lengths of the probes 53 may be substantially equal to each other. In addition, each probe 53 is disposed on an exclusive probe holder 52 thereof. Therefore, if the probe 53 is damaged and needs to be exchanged, only the damaged probe 53 is exchanged.

Referring to FIG. 15, in an embodiment, the first half hole 51A1 is located on one side of the first substrate 51A, and the second half hole 51B1 is located on one side of the second substrate 51B. The first half hole 51A1 of the first substrate 51A is opposite to the second half hole 51B1 of the second substrate 51B, so that the through hole 51a is enabled to be located at a center position of the substrate 51.

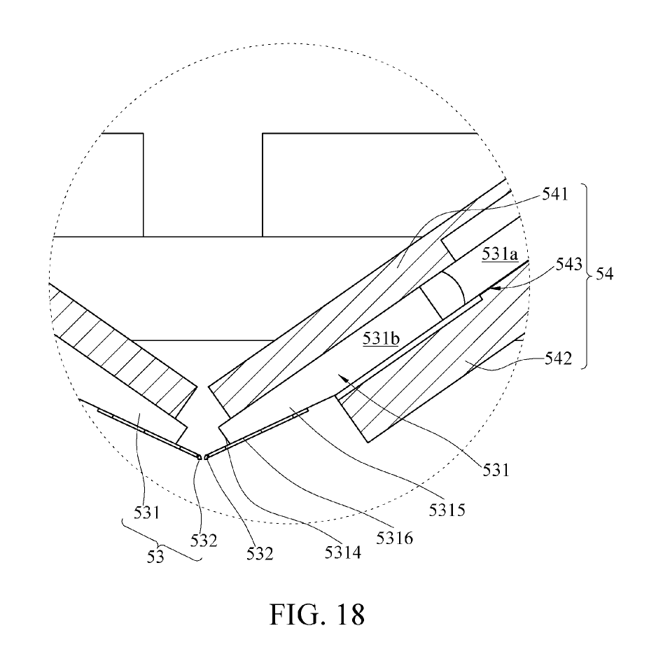

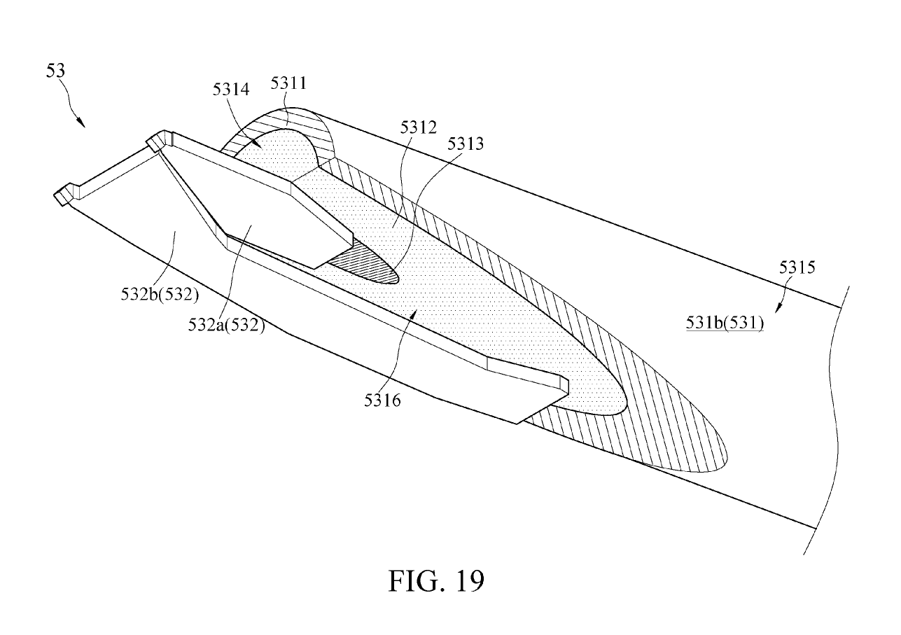

Referring to FIG. 17 and FIG. 18 again, in an embodiment, the probe holders 52 each has a bottom surface 521, a front end face 522, and a support surface 523. The front end face 522 connects the support surface 523 and the bottom surface 521. Herein, the bottom surface 521 of the probe holder 52 abuts against the upper surface F1 of the substrate 51, the front end face 522 is close to a contour of the through hole 51a, and there is an included angle between an extension direction of the support surface 523 and an extension direction of the substrate 51. Included angles of the probe holders 52 may be the same or different. Further, the front end face 522 has a front end height H in a direction vertical to the substrate 51, and front end heights H of the probe holders 52 may be the same or different. The support surface 523 of the probe holder 52 further includes a probe slot 5231. The probe slot 5231 extends to the support surface 523 and has an included angle with the upper surface F1 of the substrate 51. The probes 53 are individually disposed in the probe slots 5231 and extend towards the through hole 51a. The probe slots 5231 limit the probes 53 at particular positions on the support surface 523.

Referring to FIG. 17 and FIG. 18, in an embodiment, the probes 53 each includes a probe body 531, a detection member 532, and a signal contact 533. The probe body 531 is fixed at the probe holder 52. The detection member 532 and the signal contact 533 are respectively electrically connected to two ends of the probe body 531. The detection member 532 is configured to be in point contact with a welding pad of the to-be-tested object. The signal contact 533 is configured to electrically connect a tester and to transmit a test signal.

It should be noted that, to adapt to a finer circuit structure, the detection member 532 is usually tiny needle-shaped, so as to correspond to a welding pad configuration that is more subtle. Therefore, the volume of the detection member 532 is usually smaller than the volume of the signal contact 533. In this way, when detection members 532 need to be arranged in correspondence to a position of the welding pad of the to-be-tested object, signal contacts 533 having a relatively larger volume cannot be arranged in a same arrangement density or at a same position. In this way, the included angle between the support surface 523 and the substrate 51 or the front end height H may be changed to adjust an included angle or a position of the probe or the signal contact 533. By enabling the detection member 532 to correspond to the position of the welding pad of the to-be-tested object, the lengths of paths of the probes 53 from the detection member 532 to the signal contact 533 are approximately equal to each other, and there is no interference between the signal contacts 533.

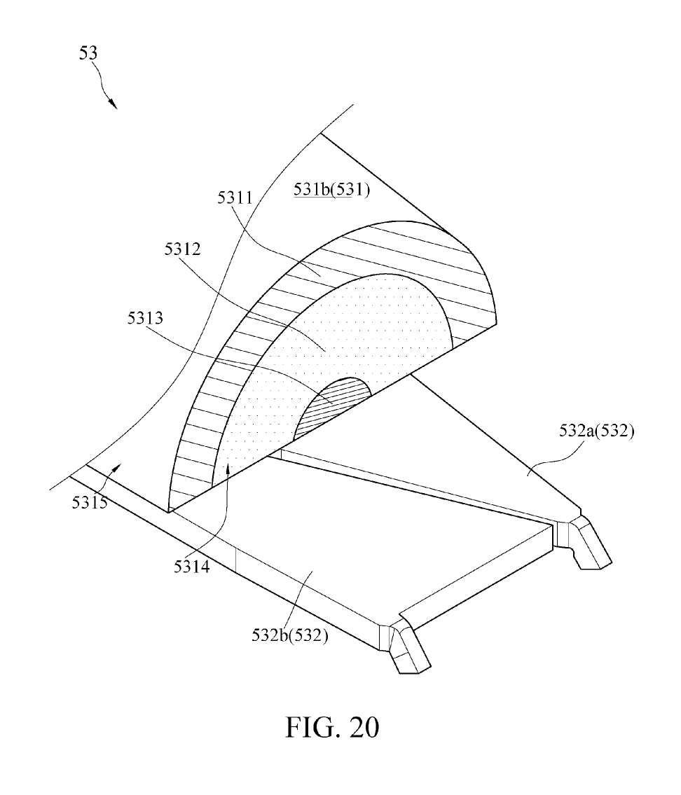

Referring to FIG. 19 and FIG. 20, in an embodiment, the probe body 531 is round bar-shaped, is a semi rigid probe body, and successively includes, from outside to inside, an external conductor 5311, an insulation layer 5312, and an internal conductor 5313 that are coaxially disposed. The external conductor 5311 and the internal conductor 5313 are insulated and isolated from each other by using the insulation layer 5312. Moreover, materials of the external conductor 5311 and the internal conductor 5313 of the probe body 531 are metals, for example, brass, beryllium copper, tungsten steel, or rhenium tungsten; and the external conductor 5311 of the probe body 531 is, for example, a copper tube. A material of the insulation layer 5312 may be a polymeric composite material, for example, glass fiber, which has good mechanical strength and weatherability; or may be polytetrafluoroethylene (PTFE) or polyetheretherketone (PEEK). The insulation layer 5312 of the probe body 531 has a dielectric constant, so as to be used at a particular frequency band width.

Referring to FIG. 16 and FIG. 17, the probe body 531 may further be grouped into a first section 531a and a second section 531b. The first section 531a of the probe body 531 is fixed at the probe holder 52. The detection member 532 is fixed at the second section 531b. There is a bending angle σ between the first section 531a and the second section 531b. Bending angles σ of the probes 53 may be different from each other, but the bending angles σ of at least two of the probes 53 are different. Moreover, second sections 531b of the probes 53 are parallel to each other. Further, the probe body 531 uses a bent portion (a position of the bending angle σ) as a separation point of the first section 531a and the second section 531b.

Referring to FIG. 19 and FIG. 20 again, the probe body 531 has an end face 5314, a circumferential surface 5315, and a beveled surface 5316. The end face 5314 is located at one end of the second section 531b of the probe body 531, and a normal direction of the end face 5314 is roughly parallel to an axial direction of the second section 531b of the probe body 531. Moreover, the external conductor 5311, the insulation layer 5312, and the internal conductor 5313 are all exposed out of the end face 5314. The circumferential surface 5315 is defined by an outer surface of the external conductor 5311. The beveled surface 5316 extends towards the circumferential surface 5315 from the end face 5314, and chamfers the external conductor 5311, the insulation layer 5312, and the internal conductor 5313, so that the external conductor 5311, the insulation layer 5312, and the internal conductor 5313 are partially exposed out of the beveled surface 5316. In other words, the beveled surface 5316 substantially includes a tangent plane of the external conductor 5311, a tangent plane of the insulation layer 5312, and a tangent plane of the internal conductor 5313.

Similarly, referring to FIG. 19 and FIG. 20, the detection member 532 is fixedly disposed on the beveled surface 5316 of the probe body 531, and is electrically connected to the probe body 531. The detection member 532 may be fixed at the beveled surface 5316 of the probe body 531 by means of welding. In an embodiment, the detection member 532 includes a first metal sheet 532a and a second metal sheet 532b. The first metal sheet 532a and the second metal sheet 532b are manufactured by using a micro-electromechanical technique and are blade like, but are not limited thereto. The detection member 532 may also be a cantilever structure, and is configured to be in point contact with the welding pad of the to-be-tested object. The first metal sheet 532a and the second metal sheet 532b may be respectively defined to be configured to transmit a test signal and be grounded, or may be respectively defined to be configured to be grounded and transmit a test signal. For example, the first metal sheet 532a is configured to transmit a test signal and the second metal sheet 532b is configured to be grounded. Therefore, the first metal sheet 532a is not connected to the second metal sheet 532b. The probes 53 that include the first metal sheet 532a and the second metal sheet 532b may form an SG coaxial probe structure or a GS coaxial probe structure, but are not limited thereto.

In other embodiments, a third metal sheet (not shown in the figures) may further be included. The third metal sheet is electrically connected to the probe body 531. Herein, the first metal sheet 532a is configured to transmit a test signal, and the remaining are configured to be grounded, so as to form a GSG coaxial probe structure. It should be noted that the present invention does not limit transmission architecture of the probe in the embodiments of the present invention. For example, various transmission architectures of U.S. Pat. No. U.S. Pat. No. 4,871,964, U.S. Pat. No. 5,506,515, and U.S. Pat. No. 5,853,295 all fall within the protection scope of the present invention.

Referring to FIG. 15 and FIG. 16 again, in an embodiment, the plurality of probes 53 may be further grouped into a first group 53a and a second group 53b. The first group 53a is disposed on the first substrate 51A, and the second group 53b is disposed on the second substrate 51B. The probes 53 of the first groups 53a and the probes 53 of the second group 53b are disposed in a mirrored manner with respect to a first axis of symmetry C11 passing through the center of the through hole 51a of the substrate 51. Herein, the first group 53a and the second group 53b individually include two probes 53, but are not limited thereto. Further, in an embodiment, the probes 53 of the first group 53a are further disposed in a mirrored manner with each other with respect to a second axis of symmetry C12 that passes through the center of the through hole 51a and that is vertical to the first axis of symmetry C11. The probes 53 of the second group 53b are further disposed in a mirrored manner with each other with respect to the second axis of symmetry C12 that passes through the center of the through hole 51a and that is vertical to the first axis of symmetry C11.

Further, referring to FIG. 16, FIG. 17, and FIG. 18, free ends of the detection members 532 of the probes 53 of the first group 53a are arranged in a straight line and located on a same horizontal plane; and free ends of the detection members 532 of the probes 53 of the second group 53b are also arranged in a straight line and located on a same horizontal plane. In addition, the straight line formed by the free ends of the detection members 532 of the probes 53 of the first group 53a may be parallel to the straight line formed by the free ends of the detection members 532 of the probes 53 of the second group 53b. In this way, the probes 53 on the coaxial probe card device 50 are applicable to performing a probe test on the to-be-tested object.

It should be noted that the coaxial probe card device 50 is not limited to a probe test on a single to-be-tested object, but may also be applied to tests on a plurality of to-be-tested objects (multi-DUT). That is, the coaxial probe card device 50 may test a plurality of to-be-tested objects at the same time. The plurality of to-be-tested objects may be, for example, a plurality of chips on a wafer. More specifically, one of the probes 53 of the first group 53a (for example, a probe 53 in the upper portion of the first group 53a) and a probe 53 of the second group 53b (for example, a probe 53 in the upper portion of the second group 53b) that is disposed in a mirrored manner with respect to the first axis of symmetry C11 may test a first to-be-tested object. Another probe 53 of the first group 53a (for example, a probe 53 in the lower portion of the first group 53a) and a probe 53 of the second group 53b (for example, a probe 53 in the lower portion of the second group 53b) that is disposed in a mirrored manner with respect to the first axis of symmetry C11 may test a second to-be-tested object.

Further, under an actual test environment, position configuration of the plurality of to-be-tested objects may be limited due to limitation of space. Because the probes 53 on the coaxial probe card device 50 are fixed at respective probe holders 52, distributed positions of the probes 53 of the coaxial probe card device 50 may change in quantity or positions according to different test requirements. Therefore, the distributed positions of the probes 53 are highly free. For example, the probes 53 may be arranged at different positions according to different arrangement manners of the to-be-tested objects without being limited by successive probe tests. More specifically, when the probe 53 performs tests on the plurality of to-be-tested objects, the probe 53 is not limited to be in point contact with two adjacent to-be-tested objects at the same time, but the tests may be performed by skipping particular to-be-tested objects (skipping DUT).

It should be noted that because the volume of the to-be-tested object is smaller, welding pads on the to-be-tested object that are configured to contact the probes 53 are arranged in an increasingly higher density. When the probe test is performed, arrangement manner and density of the probes 53 also need to be changed according to forms of the welding pads. However, although the volumes of the probes 53 are small, the probe holders 52 for fixing the probes 53 have relative large volumes with respect to the probes 53, and need to be arranged under interference of the volume of the substrate 51 and the probe holders 52. Therefore, the detection members 532 of the probes 53 corresponding to the welding pads on the to-be-tested object are mainly used as reference in arranging the probe holders 52 and configuring the probes 53. Positions of the probe holders 52 for fixing the probes 53 are configured in consideration of not interfering with each other and being within a range of the substrate 51. Herein, an upright probe body 531 usually cannot meet the foregoing two conditions at the same time. Therefore, referring to FIG. 16, the bending angle σ between the first section 531a and the second section 531b of the probe body 531 is capable of enabling a configuration between the probe 53 and the probe holders 52 to meet the conditions described above at the same time. In addition, the front end height H may also be one of the configurations conditions for coordination in adjustment.

Further, when the bending angles σ of the probes 53 on the substrate 51 are different from each other, or the bending angles σ of at least two of the probes 53 are different, because displacement directions of the probe tests of the probes 53 in performing the probe tests are consistent, extension directions and included angles between displacement directions of the probe tests of the probes 53 that have different bending angles σ are all different. In this way, the probes 53 that have different bending angles σ generate different component forces when perform the probe tests, so that forces borne by the probes 53 are not consistent. As a result, deviations may be generated to the probes 53 when the probe tests are performed. Further, probe traces of the welding pads of the to-be-tested object are not consistent, resulting in that specifications of a subsequent packaging process do not satisfy requirements. It should be noted that the bending angles σ being different does not include a case of symmetrical angles or the angular mirroring.

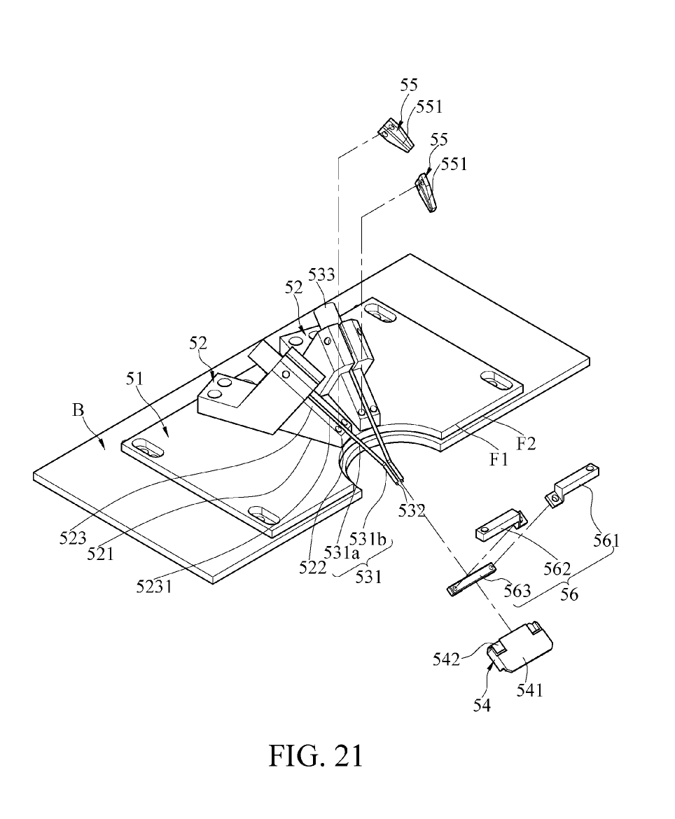

Therefore, in an embodiment, referring to FIG. 21, the limit assembly 54 sheathes around and fixes the probe body 531 of each probe 53, so as to inhibit a displacement of each probe 53 with respect to the probe holder 52, thereby improving consistency of the probe traces of the welding pads of the to-be-tested object. In an embodiment, referring to FIG. 18, the limit assembly 54 includes a first component 541, a second component 542, and a portion to pass through 543. The first component 541 docks the second component 542 to define the portion to pass through 543. The probe body 531 of each probe 53 is formed through the portion to pass through 543, and an adhesive is filled or coated in the portion to pass through 543 to fixedly bond the probe body 531 and the limit assembly 54.

Referring to FIG. 18 again, in an embodiment, both the first component 541 and the second component 542 are of sheet body structures. An aspect of the portion to pass through 543 is defined between the first component 541 and the second component 542 after the first component 541 and the second component 542 are bonded, but is not limited thereto. The portion to pass through 543 may also be defined by a single structure body having a closed contour.

Herein, referring to FIG. 18 again, the probe body 531 of each probe 53 passes through the portion to pass through 543. The detection member 532 at a rear end of the second section 531b that is located at the probe body 531 extends out of the portion to pass through 543. The adhesive may be filled in the portion to pass through 543 to fixedly bond the probe body 531 to the first component 541 and the second component 542. The adhesive may be an epoxy or another adhesive. Herein, the epoxy may be filled in the portion to pass through 543 after the probe body 531 passes through the first component 541 and the second component 542. After the epoxy is solidified, the probe body 531 may be fixedly bonded to the first component 541 and the second component 542. In this way, although the extension directions of the probes 53 may be different from the displacement directions of the probe tests, and forces borne by the probes 53 are not the same, the probes 53 are firmly fixed in the portion to pass through 543 by using the limit assembly 54, so that the probes 53 would not slide with respect to the probe holders 52 in the process of performing the probe test, so as to improve consistency of the probe traces of the welding pads of the to-be-tested object.

Further, a coverage range of the adhesive filled or coated in the portion to pass through 543 may cover the entire or a part of the portion to pass through 543, and may merely separately cover a part of the or the entire first section 531a of the probe 53, separately cover a part of the or the entire second section 531b of the probe 53, or cover a part of the or the entire first section 531a and second section 531b at the same time. Certainly, when the coverage range of the adhesive filled or coated in the portion to pass through 543 is not limited, the required coverage range may be adjusted according to the work or conditions of the probe test, so as to achieve best stability.

Further, referring to FIG. 21, based on that the probes 53 are firmly fixed in the portion to pass through 543, in an embodiment, the coaxial probe card device 50 may be provided with a plurality of extension arms 55 to reduce the forces borne by the probes 53, thereby further ensuring stability of the probes 53. A quantity of the extension arms 55 corresponds to a quantity of the probes 53. Each extension arms 55 is of a sheet body structure, and the extension arm 55 has a sleeve slot 551. One end of each extension arm 55 is fixed on the support surface 523 of the probe holder 52, and is sheathed on the probe body 531 of the probe 53 by using the sleeve slot 551. Moreover, the other end of each extension arm 55 extends into a range of the through hole 51a. In this way, the probe 53 that originally goes beyond the support surface 523 and extends into the through hole 51a is in a cantilever manner. Through positioning the extension arm 55, a portion of the probe 53 that is covered by the extension arm 55 is positioned and is in a cantilever manner, so that a force arm length of the probe 53 when bearing a force may be reduced, thereby reducing the force borne by the probe 53. Therefore, the consistency of the probe traces can be further improved after the probe 53 performs the probe test on the welding pad of the to-be-tested object.

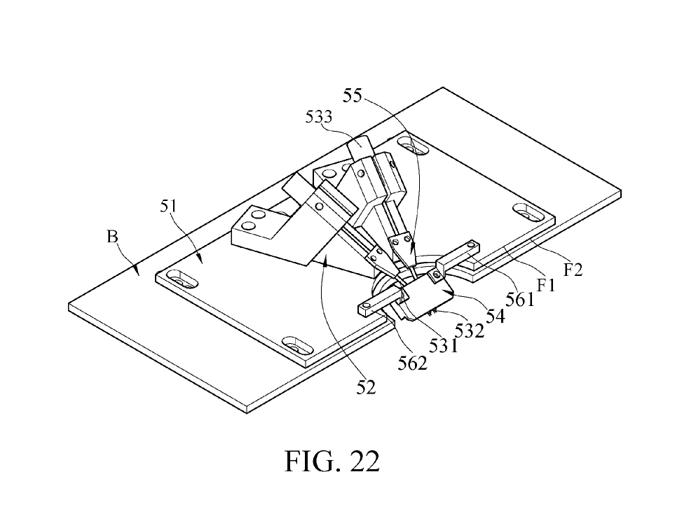

In addition, in an embodiment, based on that the probes 53 are firmly fixed in the portion to pass through 543, the coaxial probe card device 50 may also be further provided with a plurality of substrate connection assemblies 56 to provide positioning forces for stabilizing the probes 53. Referring to FIG. 21 and FIG. 22, the substrate connection assembly 56 has a first connection section 561, a second connection section 562, and a bonding section 563. The bonding section 563 is disposed between the first component 541 and the second component 542. One end of the first connection section 561 is connected to a surface of the substrate 51, and the other end is connected to one end of the bonding section 563 and the limit assembly 54 through a helical locking member. One end of the second connection section 562 is connected to the substrate 51, and the other end is connected to the other end of the bonding section 563 and the limit assembly 54 through the helical locking member. In this way, the bonding section 563 is connected between the first connection section 561 and the second connection section 562, and the limit assembly 54 is connected to the substrate 51. In this way, the substrate connection assembly 56 further provides a force for fixing the limit assembly 54 to the substrate 51, so that the limit assembly 54 fixing the probe 53 is in a more stable state, and the consistency of the probe traces is further improved after the probe 53 performs the probe test on the welding pad of the to-be-tested object.

However, the stability of the probes 53 is considered as disclosed in the above embodiments. In addition, in an embodiment, referring to FIG. 16, applicability of the entire coaxial probe card device 50 is further considered. With diversified development of electronic products, the coaxial probe card device 50 also needs to correspond to to-be-tested objects of different specifications and patterns. Therefore, the coaxial probe card device 50 may further include a bottom plate B. The bottom plate B has a plurality of positioning holes B1. The first substrate 51A has a plurality of first elongate holes 511a, and the second substrate 51B has a plurality of second elongate holes 511b. The first elongate holes 511a of the first substrate 51A may be positioned on different positioning holes B1 correspondingly. The second elongate holes 511b of the second substrate 51B may be positioned on different positioning holes B1 correspondingly. In this way, positions at which the first substrate 51A and the second substrate 51B are located on the bottom plate B may be changed, so as to change a relative position between the first group 53a and the second group 53b, thereby changing the distributed positions of the probes 53 on the coaxial probe card device 50. On this basis, the coaxial probe card device 50 is applicable to probe test of different to-be-tested objects.

In addition, in an embodiment, this disclosure further considers signal stability when the probe test is performed. Herein, the limit assembly 54 may be made of a wave absorbing material. The limit assembly 54 may be made of a wave absorbing material entirely, only the first component 541 is made of a wave absorbing material, only the second component 542 is made of a wave absorbing material, or both the first component 541 and the second component 542 are made of wave absorbing materials.

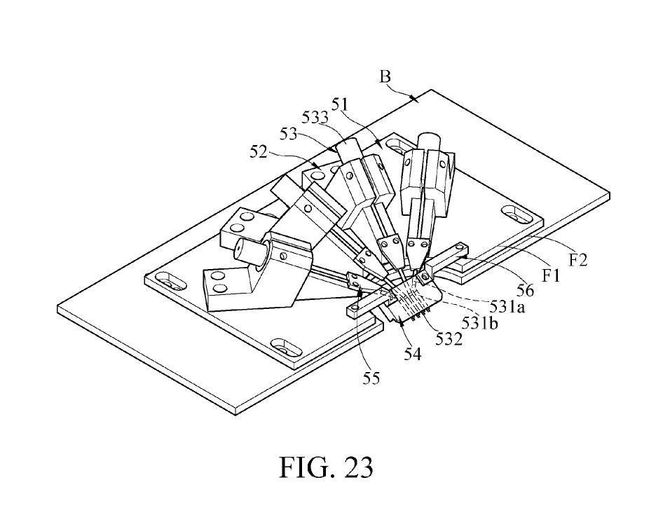

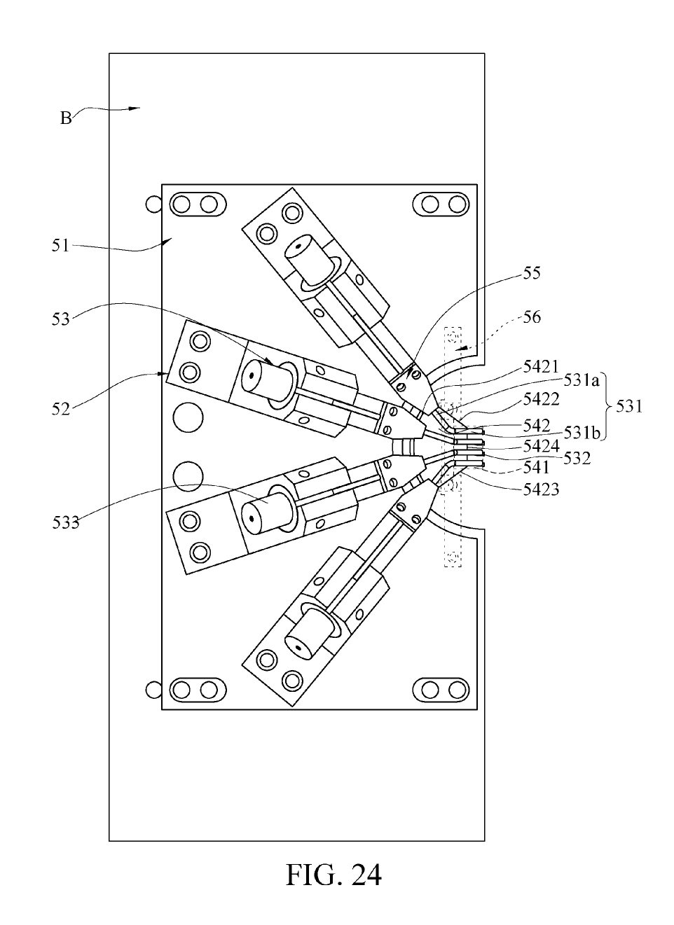

In an embodiment, referring to FIG. 23 and FIG. 24, the second component 542 of the limit assembly 54 is made of a wave absorbing material. Herein, the second component 542 is a fan-shaped sheet body and has an arc edge 5421, a first side edge 5422, a second side edge 5423, and a third side edge 5424. An extension direction of the arc edge 5421 is parallel to an extension direction of the contour of the through hole 51a. One end of the first side edge 5422 and one end of the second side edge 5423 are respectively connected to two ends of the arc edge 5421. The other end of the first side edge 5422 and the other end of the second side edge 5423 are respectively connected to two ends of the third side edge 5424. An extension direction of the third side edge 5424 is parallel to a connection line at a free end of the detection member 532 of each probe 53. Moreover, in a direction vertical to the substrate 51, an extension range of the second component 542 does not overlap the detection member 532 of each probe 53.

In this way, the second component 542 may cover as much as possible a portion of the probe body 531 of each probe 53 that extends into the through hole 51a. The second component 542 that is made of a wave absorbing material can absorb reflected electromagnetic waves generated at a periphery of the coaxial probe card device 50, so as to reduce interference of the electromagnetic waves and maintain accuracy of the probe test. The wave absorbing material may be one or a combination of a resistive absorbing material, a dielectric absorbing material, or a magnetic absorbing material. The dielectric absorbing material may be made by mixing rubber, foamed plastic, or a thermoplastic polymer with a dielectric loss material, but is not limited thereto. The magnetic absorbing material may be made by mixing a magnetic ferrite or a soft magnetic metal powder with resin, rubber, or plastic, but is not limited thereto. The ferrite may be iron oxide or nickel cobalt oxide.

Further, a housing of a portion of the limit assembly 54 that is made of a wave absorbing material may be coated with a wave absorbing material, for example, aluminum foil having ethylene-propylene rubber (EPDM), aluminum foil coated with ethylene vinyl acetate (EVA), or EVA. Alternatively, the entire limit assembly 54 may be a plate. A material of the plate is, for example, a ceramic substrate including 90-99.5% of aluminum oxide (AL₂O₃) and zirconia (PSZ).

In addition, the architecture of this disclosure may also be used in coordination with a cantilever probe, for example, the cantilever probe disclosed in the Taiwan patent publication no. 200500617. A probe and a portion of a circuit may be used together with the structure of this disclosure, and the other parts are not necessary. Moreover, the cantilever probe is mainly used for providing a direct current signal or a power supply signal.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A coaxial probe card device, comprising:
a substrate, having a through hole;
a plurality of probe holders, disposed on the substrate and configured in a radial manner surrounding the through hole by using the through hole as a center, wherein each of the probe holders has a probe slot, and the probe slot is inclined with respect to a surface of the substrate and extends towards the through hole; and
a plurality of probes, individually disposed in the probe slots of the probe holders.

2. The coaxial probe card device according to claim 1, wherein the lengths of all the probes are equal to each other.

3. The coaxial probe card device according to claim 2, wherein each of the probes has a first section and a second section, the first section is disposed in the probe slot, and the second section is bent with respect to the first section and passes through the through hole.

4. The coaxial probe card device according to claim 3, wherein these probes are grouped into a first group and a second group, the probes of the first group and the probes of the second group are disposed in a mirrored manner.

5. The coaxial probe card device according to claim 4, wherein tips of second sections of the probes of the first group are arranged in a straight line and are located on a same horizontal plane, and tips of second sections of the probes of the second group are also arranged in a straight line and are located on a same horizontal plane.

6. The coaxial probe card device according to claim 5, wherein the straight line formed by the tips of the second sections of the probes of the first group is parallel to the straight line formed by the tips of the second sections of the probes of the second group.

7. The coaxial probe card device according to claim 3, wherein the second sections of any three of the probes are not coplanar with each other.

8. The coaxial probe card device according to claim 1, wherein the probes each comprises a probe body and a detection member, the probe body has a first section and a second section, the first section of the probe body is fixed at the probe holder, the detection member is fixed at the second section of the probe body, there is a bending angle between the first section and the second section of the probe body, and bending angles of at least two of the plurality of probes are different; and
the coaxial probe card device further comprises a limit assembly that is sheathed around and fixed at the probe bodies of the plurality of probes, the limit assembly comprises a portion to pass through, second sections of the probe bodies of the plurality of probes pass through the portion to pass through, the detection member penetrates out of the portion to pass through, and an adhesive is disposed between the portion to pass through and the probe bodies, to fixedly bond the probe bodies and the limit assembly.

9. The coaxial probe card device according to claim 8, wherein the adhesive in the portion to pass through covers the second section.

10. The coaxial probe card device according to claim 8, wherein a coverage area of the adhesive in the portion to pass through extends from the first section to the second section.

11. The coaxial probe card device according to claim 8, wherein the limit assembly further comprises a first component and a second component, the first component and the second component are closed to define the portion to pass through, and the probe bodies of the plurality of probes are partially located between the first component and the second component.

12. The coaxial probe card device according to claim 8, further comprising a plurality of extension arms, wherein each of the extension arms respectively has a sleeve slot, one end of each of the extension arms is fixed at each of the probe holders and is sheathed on the probe body by using the sleeve slot, and the other end of each of the extension arms extends to a range of the through hole.

13. The coaxial probe card device according to claim 8, further comprising a substrate connection assembly, wherein the substrate connection assembly is connected to the limit assembly and the substrate.

14. The coaxial probe card device according to claim 8, wherein the second sections of the probe bodies are parallel to each other.

15. The coaxial probe card device according to claim 11, wherein the second component of the limit assembly is made of a wave absorbing material.

16. The coaxial probe card device according to claim 15, wherein in a direction vertical to the substrate, an extension range of the second component does not overlap the detection member of each of the probes.

17. The coaxial probe card device according to claim 15, wherein the first component of the limit assembly is made of a wave absorbing material.
